(19) United States
(12) Patent Application Publication
(10) Pub. No.: US 2007/0218696 A1
(43) Pub. Date: Sep. 20, 2007

(54) Dry etching method

(76) Inventors: Kenichi Kuwabara, Hikari-shi (JP); Satoshi Une, Kudamatsu-shi (JP); Tomoyoshi Ichimaru, Kudamatsu-shi (JP); Masamichi Sakaguchi, Kudamatsu-shi (JP); Naoki Yasui, Kudamatsu-shi (JP)

Correspondence Address: ANTONELLI, TERRY, STOUT & KRAUS, LLP, 1300 NORTH SEVENTEENTH STREET, SUITE 1800, ARLINGTON, VA, 22209-3873, US

(21) Appl. No.: 11/509,736

(22) Filed: Aug. 25, 2006

(30) Foreign Application Priority Data
Mar. 17, 2006 (JP) 2006-074020

(51) Int. Cl. H01L 21/465

(52) U.S. Cl. 438/706; 438/710

(57) ABSTRACT

The invention provides a method for processing vertical gate patterns while reducing the Si substrate recess dimension caused by overetching. The invention provides a dry etching method for processing a gate pattern by performing a main etching process (b) and then an overetching process on a gate pattern layer 12 of a semiconductor substrate 10, wherein the overetching process (c) is performed using a composite gas having added to an etching gas containing HBr gas a gas represented by a general formula of CxHy or at least one gas selected from CO and CO₂ gases.

The present application is based on and claims priority of Japanese patent application No. 2006-74020 filed on Mar. 17, 2006, the entire contents of which are hereby incorporated by reference.

### BACKGROUND OF THE INVENTION

1. Field of the Invention

The present invention relates to a method for etching semiconductor devices. More specifically, the present invention relates to a dry etching method for processing vertical gate patterns on semiconductor devices, capable of reducing the occurrence of damages on the Si substrate disposed under a gate oxide film caused by ion injection during etching of the gate pattern, and preventing the occurrence of abnormal profiles such as side etch and the like.

2. Description of the Related Art

Recently, the gate oxide films are reduced more and more in thickness in order to increase the processing speed in manufacturing semiconductor devices. However, when dry etching is performed during the process for forming gate patterns in which ions generated in the plasma are injected to the wafer surface via RF bias, there is a drawback in that injected ions permeated through the thin gate oxide film cause damage to the Si substrate disposed under the gate oxide film. This damage on the Si substrate causes a phenomenon in which the Si substrate is recessed (Si recess). It is known that if the recess dimension of the Si substrate is large, it may affect the properties of the device, so it is an important factor to reduce the Si recess dimension in order to improve the performance of the device.

According to the prior art dry etching method, it was necessary to apply a relatively high RF bias in order to maintain a vertical process profile while preventing areas of the gate oxide film from being unprocessed by optimizing the gas to be added such as oxygen. However, according to this method, the ion injection energy to the wafer becomes high, causing the Si recess dimension to be increased.

In order to process the polysilicon vertically while maintaining a low Si recess quantity during overetching, for example, non-patent document 1 (2005 Dry Process International Symposium, sections 10-16, pages 271-272) discloses a method for suppressing the side etch of polysilicon using inorganic halide gas not including carbon. According to this method, if halogen (such as Cl) is contained in the overetching gas, a large amount of C is required to generate reaction products with depositing properties, and if O₂ is contained, even greater amount of C is required.

### SUMMARY OF THE INVENTION

The present invention is aimed at improving the reliability of the device by reducing the recess dimension of the Si substrate caused by overetching during the dry etching process, and processing a gate pattern with a vertical profile.

The above problem can be solved by reducing the output of RF applying bias to the electrode and adjusting the plasma density by varying the process parameters, according to which the ion injection energy to the wafer is reduced and the injection of ions to the Si substrate is suppressed by controlling reaction products through added gas, and by protecting the side walls of the gate pattern.

In other words, the above objects can be achieved by the present invention providing a dry etching method for processing a gate pattern by performing an overetching process after performing a main etching process on a gate pattern layer of a semiconductor wafer, the method comprising performing the overetching process using a composite gas having added to an etching gas containing HBr gas a gas represented by a general formula of CxHy or at least one gas selected from CO and CO₂ gases.

Furthermore, the above objects can be achieved by the present invention providing a dry etching method characterized in that the gas represented by a general formula of CxHy added to the HBr gas during the overetching process is CH₄, and the amount thereof is within the range of 2 to 20 percent of the HBr gas for performing the overetching process; or in that the gas contained in the Ar gas added to the etching gas containing HBr during the overetching process is a gas containing carbon atoms; or in that the energy for injecting ions in the plasma to the Si substrate via RF bias is set to 400 eV or smaller for performing the overetching process; or in that the energy for injecting ions in the plasma to the Si substrate via RF bias is set to fall within the range of 150 eV to 400 eV for performing the overetching process.

According to the present processing method, the reaction products containing carbon generated by the added gas temporarily deposits on the gate oxide film, preventing the injection of ions that attempt to permeate through the gate oxide film layer, and suppressing the ions from reaching the Si substrate. Thus, it is not necessary to reduce the ion injection energy excessively, and it becomes possible to reduce the load on the RF power supply accompanying the reduced output. Furthermore, it becomes possible to realize stable device production without deteriorating the margin of the process performances.

Simultaneously, the reaction products generated by the added gas protects the side walls of the gate pattern, suppressing the generation of defects on the process profile of the gate pattern such as the side etch profiles and notch profiles caused by the deterioration of the ion injection energy.

As described, according to the present invention, the reliability of the device can be improved by reducing the recess dimension of the Si substrate occurring by dry etching and processing the gate patterns to have vertical profiles.

### BRIEF DESCRIPTION OF THE DRAWINGS

FIG. 1 is a cross-sectional view illustrating the schematic structure of a microwave plasma etching apparatus to which the dry etching method of the present invention is applied;

FIGS. 2A, 2B and 2C are cross-sectional views of the processing steps showing the relevant portion of the structure of the semiconductor substrate subjected to the dry etching method of the present invention; and

FIG. 3 is a graph showing the relationship between the ion injection energy and Si recess dimension, and the occurrence of side etch of polysilicon according to the dry etching method.

### DETAILED DESCRIPTION OF THE PREFERRED EMBODIMENTS

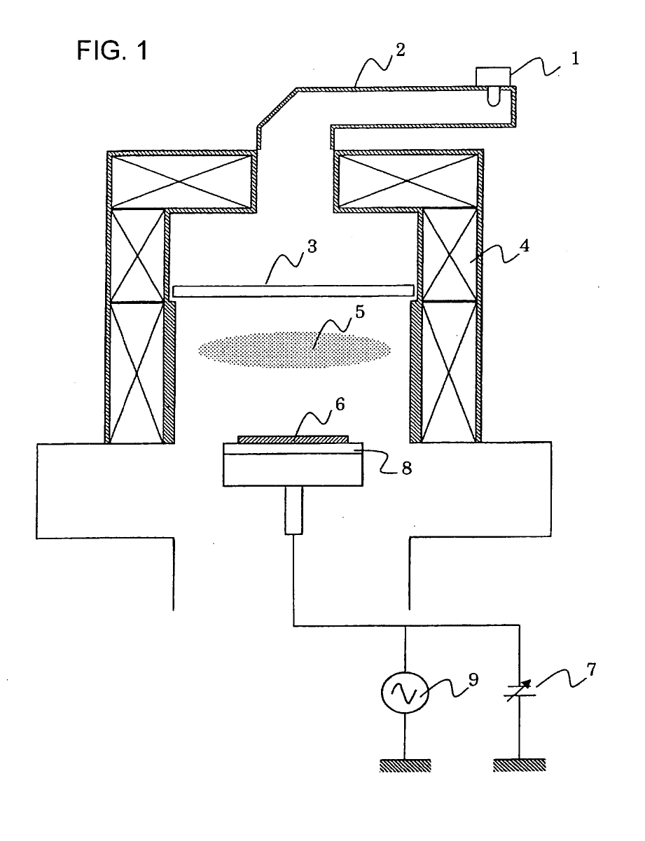

The plasma etching method according to the present invention will now be described. Microwave plasma etching apparatus, inductively-coupled plasma etching apparatus, helicon-wave plasma etching apparatus, double-frequency-excited parallel plate plasma etching apparatus and the like can be adopted as the plasma etching apparatus to which the present invention is applied. FIG. 1 illustrates an etching apparatus used in the present invention. The present embodiment is an example of a microwave plasma etching apparatus utilizing microwaves and magnetic fields as means for generating plasma. Microwaves generated by a magnetron 1 travel through a waveguide 2 and a quartz panel 3 to enter a vacuum chamber. Solenoid coils 4 are disposed around the vacuum chamber, which generate a magnetic field that acts together with the microwaves entering the vacuum chamber to cause electron cyclotron resonance (ECR). Thereby, process gases introduced from a process gas supply means not shown can efficiently be turned into plasma 5 with high density. A semiconductor wafer 6 is held onto a sample stage 8 via electrostatic chuck by applying a DC voltage to an electrode embedded in the sample stage 8 from an electrostatic chuck power supply 7. Furthermore, a high-frequency power supply 9 is connected to the electrode embedded in the sample stage 8, applying high-frequency power (RF bias) so as to provide to the ions in the plasma an accelerating potential in the perpendicular direction with respect to the wafer. The process gas used for etching is discharged after etching through an exhaust port disposed on the lower portion of the apparatus via a turbo pump—dry pump (not shown).

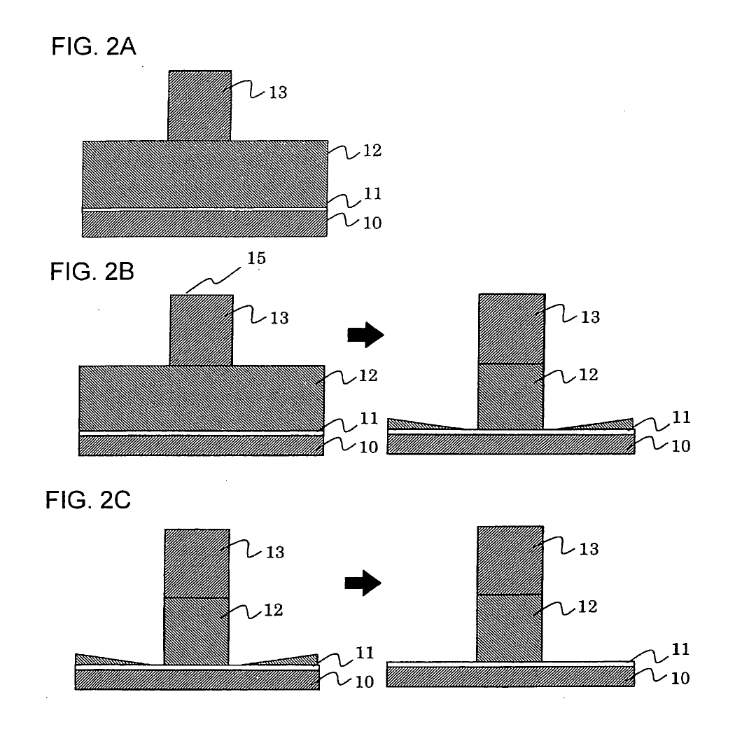

FIGS. 2A through 2C are views showing the method for manufacturing a semiconductor apparatus using the etching apparatus of FIG. 1. As illustrated, FIG. 2A shows the structure of a semiconductor wafer. FIG. 2B shows the main etching step of the polysilicon of the semiconductor wafer using a resist mask, and FIG. 2C shows the additional etching (overetching) step of the polysilicon of the semiconductor wafer.

The structure of the semiconductor wafer used in the present embodiment is illustrated in FIG. 2A. A gate oxide film 11 is deposited for 1.2 nm on a surface of a silicon substrate 10 with a diameter of 12 inches, a polysilicon film 12 is deposited for 100 nm thereon, and a photoresist 13 is deposited for 250 nm thereon in the named order, and a mask pattern is formed via photolithography and the like.

FIG. 2B shows the main etching process of polysilicon, wherein during the etching process, the interface between the polysilicon film 12 and the gate oxide film 11 is detected via an etching monitor such as an endpoint detector (EPD). A process pressure of 0.4 Pa, microwaves of 800 W, an RF bias of 50 W and a mixed gas of HBr+O₂+Cl₂ are used as the etching conditions for performing the main etching process of the polysilicon film 12. In the etching process of FIG. 2B, the etching process is discontinued when the surface of the gate oxide film 11 is first exposed. In this state, however, the polysilicon film 12 remains partially unetched on the gate oxide film 11 at stepped portions created by the influence of the base structure. In FIGS. 2A through 2C, the Si substrate 10, the gate insulating film 11 and the like are illustrated to have a flat profile, and the stepped portions formed on the base structure of the substrate are neglected.

The additional etching (overetching) step of the polysilicon film illustrated in FIG. 2C is a step for removing the polysilicon film remaining on the stepped portions of the base structure. By applying the present invention in this state in which the gate oxide film 11 is exposed, it becomes possible to prevent the ions drawn in via RF bias from permeating through the gate oxide film 11 and reaching the Si substrate 10, and simultaneously, to solve the drawbacks of defective processing profile such as side etch of the polysilicon film 12 occurring during additional etching.

In other words, the additional etching process according to the present invention performed by adding a gas composed by adding a gas containing carbon atoms to Ar to the etching gas composed of HBr+O₂ gas, and applying 500 W of microwaves and 20 W of RF bias enables to deposit reaction products including carbon atoms on the surface of the gate oxide film 11 and on the side walls of the polysilicon film 12, so as to prevent the ions from permeating through the gate oxide film 11 and suppress the generation of recesses on the Si substrate 10 disposed below the gate oxide film 11, and also suppress the generation of side etch caused by etching using low RF bias, according to which the vertical profile of the side walls of the polysilicon film 12 can be maintained and the reliability of the device can be improved.

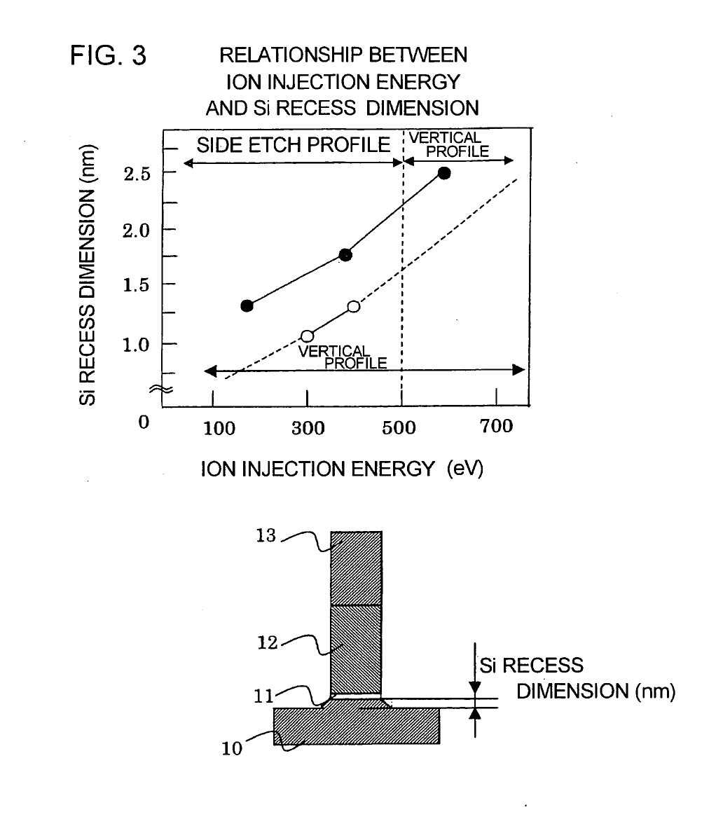

The relationship between the ion injection energy and the recess dimension of the Si substrate (Si recess dimension) in the additional etching (overetching) step of the polysilicon film is illustrated in FIG. 3. The upper portion of FIG. 3 is a diagram illustrating the relationship between the ion injection energy, the Si recess dimension and the side etch profile of the polysilicon film, and the lower portion of FIG. 3 describes the recess dimension during etching. As for etching conditions at this time, microwaves are set to 500 W and the processing pressure is set to 2.0 Pa to generate a mixed plasma composed of HBr/O₂ gases, and the RF bias applied to the electrode is increased or decreased so as to vary the ion injection energy, and the corresponding Si recess dimension is measured. The line connecting the black circles represents the etching results under the above conditions, wherein the ion injection energy were substantially 200, 400 and 600 eV. As shown in FIG. 3, when the ion injection energy is high, the ions easily reach the Si substrate and the Si recess dimension increases. According to FIG. 3, it can be recognized that in order to reduce the Si recess dimension to approximately 1.0 nm, it is necessary to suppress the ion injection energy to 100 eV or smaller.

On the other hand, with respect to the processing profile of polysilicon, the reduction of ion injection energy causes the vertical directional property of ion injection to be lost and the etching quantity of the photoresist mask to be deteriorated, by which the amount of reaction products including carbon in the plasma is reduced and the side walls of the polysilicon are no longer protected, causing generation of side etch profiles. The ion injection energy required for suppressing the side etch is approximately 500 eV, but the Si recess dimension at that time is increased to as much as approximately 2.2 nm.

According to the present embodiment, in the additional etching process of the polysilicon film of FIG. 2C, processing is performed under a condition in which the output of the RF bias is 20 W and the ion injection energy is suppressed to approximately 300 eV. Moreover, etching is performed in a mixed plasma generated by adding to the mixed gas of HBr/O₂ a mixed gas having CH₄ gas added to Ar gas which functions as the gas containing carbon, with the processing pressure set to 2.0 Pa and the microwaves to 500 W. At this time, 3 ml/min of CH₄ gas is added to the 70 ml/min of HBr gas, which means that the amount of CH₄ gas added is approximately 4% of the total etching gas flow rate of HBr gas and CH₄ gas.

The Si recess dimension of the semiconductor wafer being subjected to etching according to this method is suppressed to approximately 1.0 nm, as illustrated by the broken lines connecting the white circles of FIG. 3, and vertical process profiles without side etches and other defects were achieved. In other words, the white circles of the present embodiment represent the measured Si recess dimension and the generation of side etch profiles when the injection energy is set to 300 eV and 400 eV.

The maximum energy εmax (eV) of ions injected to the wafer can be expressed by the following expression (1).

εₘₐₓ= ε̅+Δε [Expression 1]

Here, the first term on the right-hand side of expression (1) represents the average injection energy of ions, and the second term Δε (eV) represents the injection energy spread of ions. The injection energy spread Δε is provided by the following expression (2).

$$Δ ɛ = \frac{2 e {V}_{RF}}{3 ω d} \sqrt{\frac{2 \overline{ɛ}}{{m}_{1}}} \qquad [ Expression 2 ]$$

In the above expression (2), e(C) represents the charge of electrons, V_{RF} (V) represents the voltage magnitude of the RF bias voltage, ω (rad/s) represents frequencies of the RF bias, d (m) represents the sheath thickness, and m₁ represents the ion mass.

These expressions are already known, and for further details on these expressions, refer to “Inter-University Plasma Electronics” by Hideo Sugai et al., Ohmsha, published Feb. 25, 2001.

Based on expressions (1) and (2), if the RF bias frequency is set to 400 kHz, in order to achieve a maximum injection energy of approximately 300 eV, V_{RF} should be approximately 150 V (300 Vpp). If the RF bias frequency is 1 MHz, in order to achieve a maximum injection energy of approximately 300 eV, V_{RF} should be approximately 230 V (460 Vpp). In the present embodiment, a power supply with an RF bias frequency of 400 kHz is used and the RF bias output is set to 20 W so as to control the ion injection energy to approximately 300 eV, but as shown in expressions (1) and (2), the setting of the power supply output is varied according to the RF bias frequency being used.

At this time, the etching rate of the polysilicon film is reduced as the amount of CH₄ gas being added is increased, and from a certain amount, the etching stops. In contrast, if the added amount is too small, the supply of carbon is reduced, and the polysilicon is subjected to side etch. In the present embodiment, a mixed gas having 4% of CH₄ added to Ar gas is used, but similar effects can be achieved via reaction products containing carbon generated during reaction by using gases containing carbon molecules such as gases containing C or CH, for example, CCl₄, C₂H₂, C₂H₄, C₂H₆, C₃H₃, C₃H₈, C₆H₆, CO, CO₂ and CS₂ gases. Further, the optimum quantities of the gases to be added depend on etching conditions and the structure of the material to be etched, so it becomes necessary to optimize the etching conditions and the addition quantity of gases containing C or CH.

In order to put the present invention to practice, it is preferable that the amount of CH₄ is within the range of 2 to 10% of the HBr flow rate.

Moreover, since the reaction products generated by adding a gas containing CH₄ not only act to protect the side walls of the polysilicon film but also deposit on the gate oxide film, they function to prevent the injected ions from reaching the Si substrate. According to this operation, it is no longer necessary to reduce the ion injection energy to approximately 160 eV in order to suppress the Si recess dimension to approximately 1.0 nm, and the Si recess dimension can be suppressed to approximately 1.0 nm even when the energy is as high as 300 eV. The Si recess dimension can be suppressed to approximately 1.5 nm by merely reducing the injection energy to approximately 400 eV.

The output of RF bias can be set high if the ion injection energy is maintained at a high level, according to which stable RF power supply can be maintained, and the process performance can be stabilized without being easily affected by the change in properties with time of the inner walls of the etching chamber (vacuum chamber) or the like.

As described, according to the present embodiment, the Si recess dimension can be suppressed to approximately 1.0 nm, and the polysilicon film can be processed to realize a vertical profile.

The present embodiment is performed based on process conditions optimized for processing semiconductor wafers of semiconductor devices, but the conditions of the method for etching the polysilicon film 12 are not restricted to those disclosed in the present embodiment.

The present embodiment applies the present invention to a semiconductor wafer having a photoresist mask, but the present invention can be applied to other semiconductor wafers having inorganic film masks such as SiN, SiON, SiO₂ and the like.

Moreover, the present embodiment applies the present invention to a plasma etching apparatus utilizing microwaves and magnetic fields, but the present invention can be applied regardless of how plasma is generated, and equivalent effects can be achieved by applying the invention to helicon wave etching apparatuses, inductively-coupled etching apparatuses, capacitively-coupled etching apparatuses and the like.

As described, the present invention provides a dry etching method for processing gate patterns by performing an overetching process after performing a main etching process on a gate pattern layer on a semiconductor substrate, capable of etching the polysilicon film vertically without damaging the Si substrate disposed under the gate oxide film layer.

What is claimed is:

1. A dry etching method for processing a gate pattern by performing an overetching process after performing a main etching process on a gate pattern layer of a semiconductor wafer, the method comprising:
performing the overetching process using a composite gas having added to an etching gas containing HBr gas a gas represented by a general formula of CxHy or at least one gas selected from CO and CO₂ gases.

2. The dry etching method according to claim 1, wherein the gas represented by a general formula of CxHy added to the HBr gas during the overetching process is CH₄, and the amount thereof is within the range of 2 to 20 percent of the HBr gas for performing the overetching process.

3. The dry etching method according to claim 1, wherein the gas added to the etching gas containing HBr during the overetching process is a gas containing carbon atoms.

4. The dry etching method according to claim 1, wherein the energy for injecting ions in the plasma to the Si substrate via RF bias is set to 400 eV or smaller for performing the overetching process.

5. The dry etching method according to claim 1, wherein the energy for injecting ions in the plasma to the Si substrate via RF bias is set to fall within the range of 150 eV to 400 eV for performing the overetching process.
